(19) United States
(12) Patent Application Publication
(10) Pub. No.: US 2015/0228528 A1
(43) Pub. Date: Aug. 13, 2015

(54) CHUCKING CAPABILITY FOR BOWED WAFERS ON DSA

(71) Applicant: Applied Materials, Inc., Santa Clara, CA (US)

(72) Inventor: Mehran BEHDJAT, San Jose, CA (US)

(21) Appl. No.: 14/596,411

(22) Filed: Jan. 14, 2015

Related U.S. Application Data
(60) Provisional application No. 61/987,218, filed on May 1, 2014.
(60) Provisional application No. 61/937,212, filed on Feb. 7, 2014.

(51) Int. Cl. H01L 21/683; H01L 21/67

(52) U.S. Cl. CPC H01L 21/6838; H01L 21/67103

(57) ABSTRACT

Embodiments described herein generally relate to a heated chuck. The chuck includes a first surface and a second surface opposite the first surface. The first surface includes a depression defined by a substantially non-spherical surface. The non-spherical surface is configured to support a concaved substrate and to hold the concaved substrate in a stable manner for processing.

### CROSS-REFERENCE TO RELATED APPLICATIONS

This application claims priority to U.S. Provisional Patent Application Ser. No. 61/937,212 (APPM/021570USAL), filed Feb. 7, 2014, and to U.S. Provisional Patent Application Ser. No. 61/987,218 (APPM/021570USAL2), filed May 1, 2014, which are herein incorporated by reference.

### BACKGROUND

1. Field

Embodiments described herein generally relate to semiconductor manufacturing, and more specifically, to a chuck heater pedestal for use in a processing chamber.

2. Description of the Related Art

Thermal processing is commonly practiced in the semiconductor industry. Semiconductor substrates are subjected to thermal processing in the context of many transformations, including doping, activation, and annealing of gate source, drain, and channel structures, siliciding, crystallization, oxidation, and the like. Over the years, techniques of thermal processing have progressed from simple furnace baking to various forms of increasingly rapid thermal processing such as RTP, spike annealing, and laser annealing.

A thermal processing chamber, such as a dynamic surface anneal (DSA) chamber, may include a vacuum chuck heater pedestal that holds the substrate at a predetermined temperature for laser annealing. If the substrate is flat or reasonably flat, it can be vacuum chucked and laser processed. However, if the substrate is curved because of a coating with a material with a very different coefficient of thermal expansive (CTE), or an inherent tensile stress, the vacuum chucking does not hold the substrate in a stable manner for laser processing. It is also noted, for a concaved substrate, the concavity is worsened because the center of the substrate touches or is close to the hot pedestal. Thus, concaved substrate may cause issues not only for vacuum chucks, but also for other types of heated chucks such as electrostatic chucks.

Therefore, an improved heated chuck is needed.

### SUMMARY

Embodiments described herein generally relate to a heated chuck. The chuck includes a first surface and a second surface opposite the first surface. The first surface includes a depression defined by a substantially non-spherical surface. The non-spherical surface is configured to support a concaved substrate and to hold the concaved substrate in a stable manner for processing.

In one embodiment, an apparatus is disclosed. The apparatus includes a heated substrate support which includes a heating element embedded in the substrate support, a first surface and a second surface opposite the first surface. The first surface includes an outer region defining a plane that is substantially parallel to the second surface, and a non-spherical surface surrounded by the outer region. The non-spherical surface includes an inner region disposed between the plane defined by the outer region and the second surface, and a connecting region connecting the outer region and the inner region.

In another embodiment, an apparatus is disclosed. The apparatus includes a heated vacuum chuck which includes a heating element embedded in the vacuum chuck and a substrate support surface. The substrate support surface includes an outer region and an inner region, and the inner region is disposed below the outer region. The substrate support surface further includes a connecting region connecting the outer region and the inner region, and the connection region and the inner region are non-spherical. The heated vacuum chuck further includes a plurality of channels formed on the inner region and the connecting region.

In another embodiment, a processing chamber is disclosed. The processing chamber includes a chamber body and a chuck assembly disposed in the chamber body. The chuck assembly includes a heated chuck and the heated chuck includes a heating element embedded in the chuck, a first surface and a second surface opposite the first surface. The first surface includes an outer region defining a plane that is substantially parallel to the second surface, and a non-spherical surface surrounded by the outer region. The non-spherical surface includes an inner region disposed between the plane defined by the outer region and the second surface, and a connecting region connecting the outer region and the inner region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a cross-sectional view of a process chamber with a heated chuck assembly in accordance with one embodiment.

FIGS. 2A and 2B schematically illustrate an enlarged view of a heated chuck of the heated chuck assembly in accordance with one embodiment.

FIG. 3 schematically illustrates a top view of the heated chuck in accordance with one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to a heated substrate support. The substrate support, which may be a chuck, includes a first surface and a second surface opposite the first surface. The first surface includes a depression defined by a substantially non-spherical surface. The non-spherical surface is configured to support a curved substrate and to hold the concaved substrate in a stable manner for processing.

Embodiments described herein will be described below in relation to a laser processing chamber. An example of a laser processing chamber that may benefit from the embodiments described herein is the ASTRA® chamber available from Applied Materials, Inc., of Santa Clara, Calif. Other types of chambers that operate at high temperatures may also benefit from the teachings disclosed herein, and in particular, processing chambers that use lasers as a means for thermal processing which may be a part of a semiconductor wafer processing system such as the CENTURA® system which is available from Applied Materials, Inc., of Santa Clara, Calif. It is contemplated that other processing chambers, including those available from other manufacturers, may be adapted to benefit from the invention.

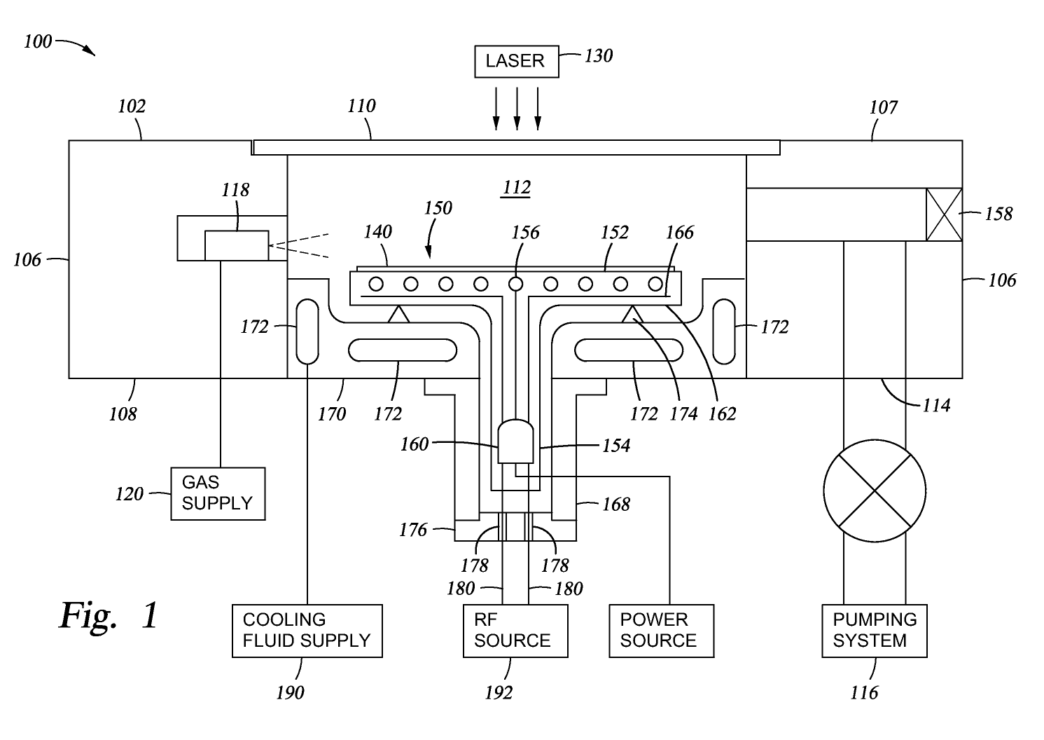

FIG. 1 schematically illustrates a cross-sectional view of a process chamber 100 with a heated substrate support assembly 150 in accordance with one embodiment. The heated substrate support assembly 150 facilitates improved substrate processing by holding a concaved substrate in a stable manner and by subjecting the concaved substrate to a uniform high temperature.

In one embodiment, the process chamber 100 is a laser processing chamber. The process chamber 100 comprises a chamber body 102. The chamber body 102 has sidewalls 106, a bottom 108, and a window 110 that define a process volume 112. The process volume 112 is typically accessed through a slit valve 158 in the sidewall 106 that facilitates movement of a substrate 140 into and out of the chamber body 102. In certain embodiments, the substrate 140 may be a wafer, such as a wafer used in semiconductor processing. The sidewalls 106 and bottom 108 of the chamber body 102 may be fabricated from a unitary block of aluminum or other material compatible with process chemistries. The bottom 108 of the chamber 100 comprises a support piece 170 having one or more cooling channels 172 formed within the support piece 170. The one or more cooling channels 172 are coupled with a cooling fluid supply 190 configured to provide a cooling liquid or gas to the one or more cooling channels 172. The support piece 170 may comprise stainless steel. In one embodiment, the support piece 170 has an optically reflective surface facing the backside of the substrate to enhance emissivity. One or more support pins 174 are coupled with and extend above the surface of the support piece 170. The bottom 108 of the chamber 100 has a pumping port 114 formed therethrough that couples the process volume 112 to a pumping system 116 to facilitate control of pressure within the process volume 112 and to exhaust gases and byproducts during processing.

The window 110 is supported by the sidewalls 106 of the chamber body 102 and can be removed to service the interior of the chamber 100. In one embodiment, the window 110 comprises a material such as quartz. The window 110 may be held in place by any convenient means. For example the window 110 may be secured to the sidewalls 106 by bolts (not shown) passed through holes in the window 110 and seated in threaded recesses in the sidewalls 106. Alternately, a clamp ring (not shown) may be disposed around an edge of the window 110 and secured to an upper surface 107 of the chamber by bolts (not shown).

Process gas and other gases may be introduced into the process volume 112 from a gas plenum 118 coupled with a gas supply 120. In one embodiment, the gas plenum 118 is positioned so as to provide a uniform flow of gases across the surface of the substrate 140. The gas plenum 118 may be positioned in the sidewall 106 or attached to an inner surface of the sidewall 106.

A laser assembly 130 is located above the window 110. The laser assembly 130 may contain any suitable laser for performing annealing , such as a diode laser or diode laser assembly (for example a diode laser bar or array), a solid state laser, a gas laser, an excimer laser, or other convenient laser type. The laser assembly 130 may be coupled to an optical assembly (not shown) disposed between the laser assembly 130 and the window 110 for shaping radiation emitted by the laser assembly 130. In one embodiment, the laser assembly 130 may be coupled with a translation mechanism adapted to move the laser assembly 130 across the surface of the substrate 140.

The heated substrate support assembly 150 is centrally disposed within the chamber body 102 and supports the substrate 140 during processing. The heated substrate support assembly 150 may be a vacuum chuck assembly. The heated substrate support assembly 150 generally includes a substrate support 152 supported by a shaft 154 that extends through the chamber bottom 108. The substrate support 152 may have the same peripheral shape as the substrate 140. In one embodiment, the substrate support 152 is circular in shape and may be fabricated from materials such as quartz, aluminum nitride or silicon carbide, ceramics such as alumina, or combinations thereof. In one embodiment, the substrate support 152 encapsulates at least one embedded heating element 156. The heating element 156, such as an electrode, resistive heating element, or hot fluid conduit, may be coupled with a power source via electrical connector assembly 160 and controllably heats the substrate support 152 and substrate 140 positioned thereon to a predetermined temperature. In one embodiment, the heating element 156 heats the substrate 140 to a temperature of between about 20° C. and 750° C. during processing.

A lower surface 162 of the substrate support 152 is supported by the one or more support pins 174. Generally, the shaft 154 extends from the lower surface 162 of the substrate support 152 through the chamber bottom 108. A sleeve 168 circumscribes a portion of the shaft 154. In one embodiment, the sleeve 168 is coupled with the bottom of support piece 170, for example by bolting. The bottom of the sleeve 168 is coupled with a base 176. The base 176 has one or more holes 178 through which one or more RF rods 180 extend, if RF is coupled to the substrate support 152. The one or more RF rods 180 may be connected to one or more electrodes 166 that are embedded in the substrate support 152. In one embodiment, the electrodes 166 are disposed above the heating element 156. The electrodes 166 may be coupled to an RF source 192 via the RF rods 180. The electrodes 166 may alternately be coupled to a standard DC or AC power source to supply additional resistive heating.

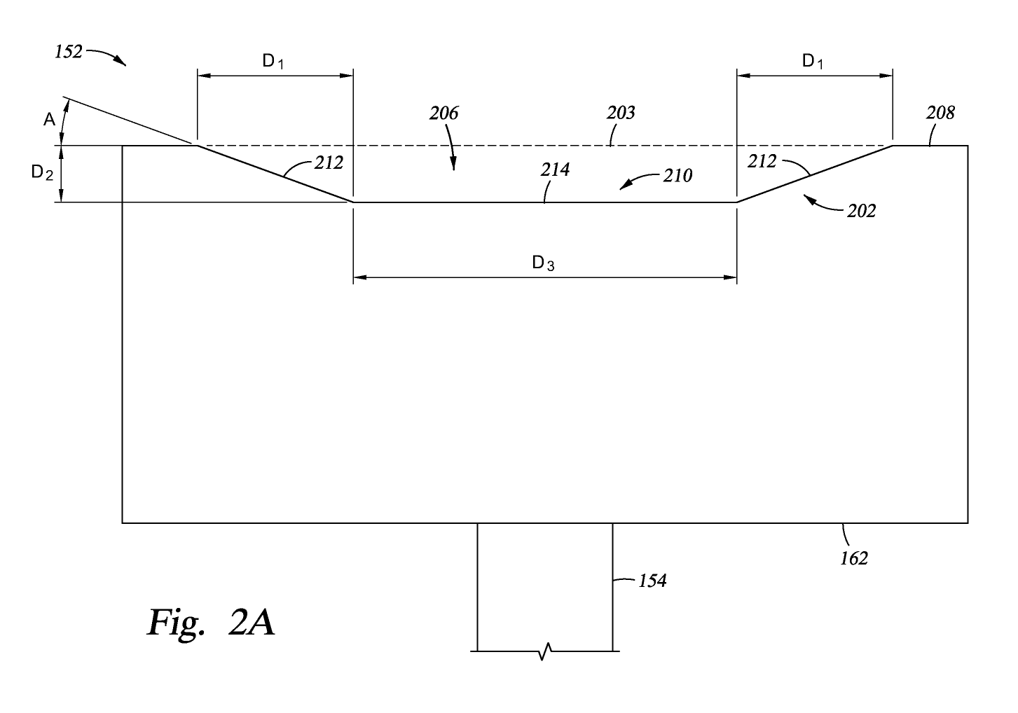

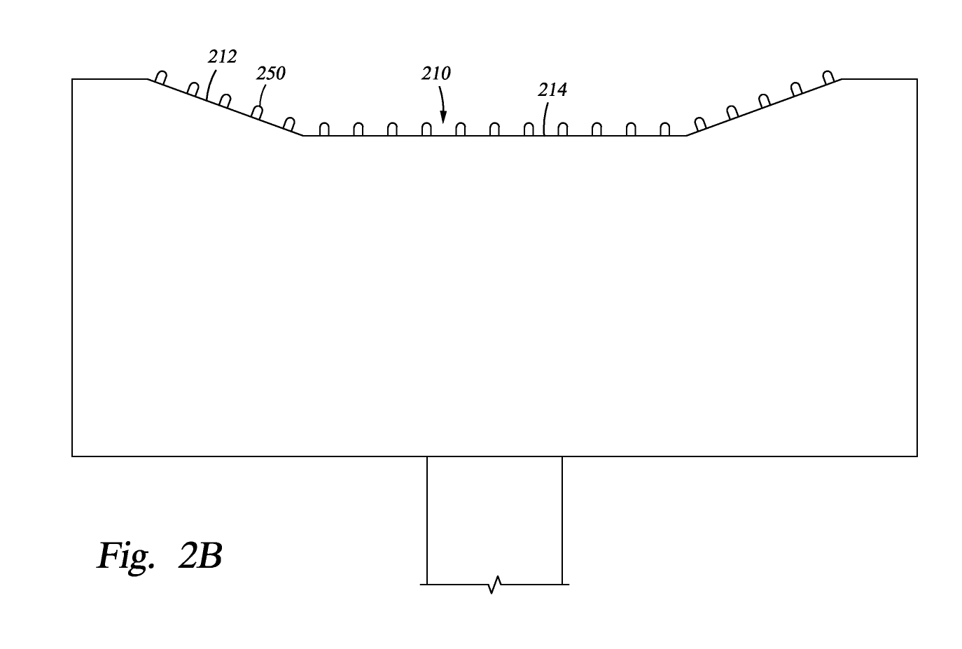

FIGS. 2A and 2B schematically illustrates an enlarged view of the substrate support 152 of the substrate support assembly 150 according to one embodiment. Components disposed in the substrate support 152, such as the heating element 156 and the electrodes 166, are omitted in FIGS. 2A and 2B for better clarity. As shown in FIG. 2A, the substrate support 152 has a first surface 202 that is configured to support a curved substrate and the lower surface 162 that is opposite the first surface 202. The first surface 202 may be non-coplanar and may have a depression 206. The first surface 202 may include an outer region 208 surrounding the depression 206. The outer region 208 may be an annulus, and may be substantially parallel to the lower surface 162. Thus, the outer region 208 may define a first plane 203 that is substantially parallel to a second plane defined by the lower surface 162. The depression 206 may be defined by a non-spherical surface 210 that is non-coplanar with the first plane defined by the outer region 208. In one embodiment, the non-spherical surface 210 includes an inner region 214 and a connecting region 212. The inner region 214 may be positioned radially inward from an inner radius of the outer region 208, as indicated by distance “D1” shown in FIG. 2A, and may be concentric with the outer region 208. The radial distance “D1” may be greater than or equal to 10 mm. The inner region 214 may be disposed below the outer region 208, such as between the first plane defined by the outer region 208 and the lower surface 162, such that when viewed through the window 110 (FIG. 1), the first surface 202 appears concave, or receding away from the window 110.

The connecting region 212 connects the inner radius of the outer region 208 to an outer radius of the inner region 214. Since the outer region 208 and the inner region 214 are non-coplanar and the inner region 214 is disposed below the outer region 208, such that there is an axial distance “D2” from the plane 203 to the inner region 214 in a direction away from the window 110, the connecting region 212 may have an angle “A” that is greater than 0 degrees and less than 90 degrees with respect to the first plane. In one embodiment, the angle “A” may be about 0.013 degrees. In one embodiment, for the ease of manufacturing, a cross-sectional profile of the connecting region 212 may be substantially linear and a cross-sectional profile of the inner region 214 may be substantially linear, such that the non-spherical surface 210 resembles an upside down cone having a flat circular bottom instead of a tip, for example a frustum. The inner region 214 may have a diameter or a length “D3” that is based on the diameter of the substrate.

The depression 206 defined by the non-spherical surface 210 helps to hold a curved substrate, such as a concaved substrate, in a stable manner and to subject the concaved substrate to a uniform thermal treatment. In some situations, the concaved substrate has a bow of about 250 microns, defined by the vertical distance from the edge of the substrate to the lowest point, typically the center, of the substrate. In other words, the bow is the perpendicular distance from a central point of the substrate to a plane defined by an edge of the substrate. An axial distance between the inner region 214 and the plane 203 defined by the outer region 208, for example the axial distance from the center of the inner region 214 and the plane 203, indicated as “D2” in FIG. 2A, may be greater than the typical bow of the concaved substrate, such as greater than or equal to 300 microns. Thus, when placing such concaved substrate on the heated substrate support 152, the lowest point of the substrate does not contact the inner region 214, providing uniform heating of the concaved substrate. The edge, or an area near the edge, of the concaved substrate may rest on the connecting region 212, and the concaved substrate is firmly held in place by a vacuum pulled through the substrate support 152.

In one embodiment, a plurality of protrusions 250 may be formed on the connecting region 212 and the inner region 214, as shown in FIG. 2B. The protrusions 250 reduce the contact area between the substrate support 152 and the substrate, thus reducing the possibility of particle contamination caused by contact with the non-spherical surface 210. In one embodiment, the height of the protrusions 250 may be from about 10 microns to about 50 microns, for example, about 25 microns, and the width or diameter of the protrusions 250 may be from about 500 microns to about 5000 microns. In one embodiment, the plurality of protrusions 250 and the non-spherical surface 210 are unitary and may be formed by, for example, either machining or bead blasting the surface of the substrate support 152 with a mask. In another embodiment, the protrusions 250 may be deposited on the non-spherical surface 210 using a deposition process and a mask pattern. In one embodiment, the substrate support 152 is 300 mm in diameter and has between 100 and 500 protrusions, for example, between 150 and 200 protrusions that contact approximately 10% of the surface area of a substrate placed thereon. In one embodiment, each protrusion 250 is 0.5 inches apart from the neighboring protrusions. In one embodiment, the protrusions 250 are arranged in a substantially linear arrangement, such as a radial or x-y grid pattern, across the non-spherical surface 210. The radial pattern may emanate from a central region, for example the center, of the non-spherical surface 210.

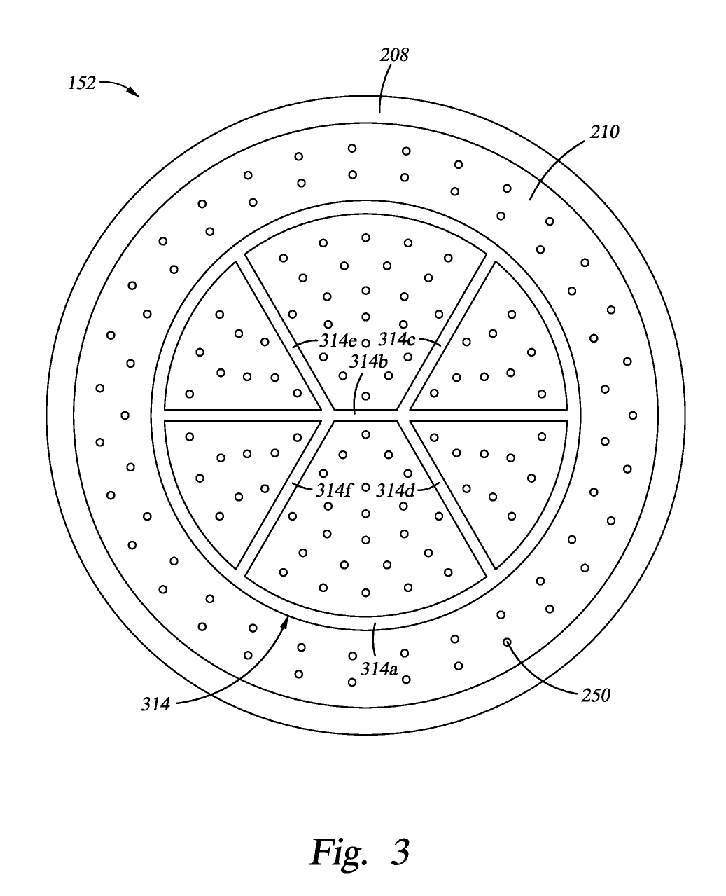

FIG. 3 schematically illustrates a top view of the heated substrate support 152 in accordance with one embodiment. As shown in FIG. 3, the outer region 208 surrounds the non-spherical surface 210, and the protrusions 250 are formed on the non-spherical surface 210. In the embodiment where the substrate support 152 is a vacuum chuck, a plurality of channels 314 may be formed on the non-spherical surface 210 and may be fluidly coupled to a vacuum pump (not shown), thereby generating reduced pressure in the area between the non-spherical surface 210 and the concaved substrate to secure the concaved substrate on the substrate support 152. The channels 314 may be formed in a symmetrical pattern for exerting uniform suction force on the substrate. As shown in FIG. 3, the channels 314 can be formed in a pattern composed of a circular channel 314a, a straight channel 314b, and two pairs of slanting channels 314c/314d, 314e/314f. The straight channel 314b may be formed along a diameter of the circular channel 314a connecting opposite sides of the circular channel 314a, and the pairs of slanting channels 314c/314d, 314e/314f may extend respectively from the straight channel 314b to the circular channel 314a, and may be mirror-reflected to each other. The channel pattern described herein is merely stated as an example, and the present invention is not limited thereto.

While the foregoing is directed to embodiments of the disclosure, other and further embodiments may be devised without departing from the basic scope thereof, and the scope thereof is determined by the claims that follow.

1. An apparatus, comprising:
a heated substrate support, wherein the substrate support comprises:
a heating element embedded in the substrate support; and
a first surface and a second surface opposite the first surface, wherein the first surface comprises:
an outer region defining a plane that is substantially parallel to the second surface; and
a non-spherical surface surrounded by the outer region, wherein the non-spherical surface comprises:
an inner region disposed between the plane defined by the outer region and the second surface; and
a connecting region connecting the outer region and the inner region.

2. The apparatus of claim 1, wherein the heated substrate support further comprises quartz, aluminum nitride, silicon carbide, alumina or combination thereof.

3. The apparatus of claim 1, wherein a radial distance between the inner region and the outer region is greater than or equal to 10 mm.

4. The apparatus of claim 1, wherein an axial distance between the plane defined by the outer region and the inner region is greater than or equal to 300 microns.

5. The apparatus of claim 1, wherein the inner region has a linear cross-sectional profile.

6. The apparatus of claim 5, wherein the inner region is circular.

7. The apparatus of claim 5, wherein the connecting region has a linear cross-sectional profile.

8. An apparatus, comprising:
a heated vacuum chuck, comprising:
a heating element embedded in the vacuum chuck; and
a substrate support surface, wherein the substrate support surface comprises:
an outer region and an inner region, wherein the inner region is disposed below the outer region;
a connecting region connecting the outer region and the inner region, wherein the connection region and the inner region are non-spherical; and
a plurality of channels formed on the inner region and the connecting region.

9. The apparatus of claim 8, wherein the heated vacuum chuck further comprises quartz, aluminum nitride, silicon carbide, alumina or combination thereof.

10. The apparatus of claim 8, wherein the outer region is an annulus that defines a plane, and the inner region is an axial distance away from the plane, wherein the axial distance is greater than or equal to 300 microns.

11. The apparatus of claim 8, wherein a radial distance between the inner region and the outer region is greater than or equal to 10 mm.

12. The apparatus of claim 8, wherein the inner region has a linear cross-sectional profile.

13. The apparatus of claim 12, wherein the inner region is circular.

14. The apparatus of claim 12, wherein the connecting region has a linear cross-sectional profile.

15. A processing chamber, comprising:
a chamber body;
a chuck assembly disposed in the chamber body, wherein the chuck assembly comprises:
a heated chuck, wherein the heated chuck comprising:
a heating element embedded in the chuck;
a first surface and a second surface opposite the first surface, wherein the first surface comprises:
an outer region that is substantially parallel to the second surface; and
a non-spherical surface surrounded by the outer region, wherein the non-spherical surface comprises: an inner region disposed between a plane defined by the outer region and the second surface; and a connecting region connecting the outer region and the inner region.

16. The processing chamber of claim 15, wherein the heated chuck further comprises quartz, aluminum nitride, silicon carbide, alumina or combination thereof.

17. The processing chamber of claim 15, wherein a radial distance between the inner region and the outer region is greater than or equal to 10 mm.

18. The processing chamber of claim 15, wherein an axial distance between the plane defined by the outer region and the inner region is greater than or equal to 300 microns.

19. The processing chamber of claim 15, wherein the inner region has a linear cross-sectional profile.

20. The processing chamber of claim 19, wherein the connecting region has a linear cross-sectional profile.
